(19) United States
(12) Patent Application Publication
(10) Pub. No.: US 2023/0205077 A1
(43) Pub. Date: Jun. 29, 2023

(54) APPARATUS AND METHOD FOR TREATING SUBSTRATE

(71) Applicant: SEMES CO., LTD., Cheonan-si (KR)

(72) Inventors: Tae Hee KIM, Yongin-si (KR); In Ki JUNG, Hwaseong-si (KR); Ki Hoon CHOI, Cheonan-si (KR); Hyo Won YANG, Seoul (KR); Won Sik SON, Yongin-si (KR); Hyun YOON, Seoul (KR)

(73) Assignee: SEMES CO., LTD., Cheonan-si (KR)

(21) Appl. No.: 18/146,693

(22) Filed: Dec. 27, 2022

(30) Foreign Application Priority Data
Dec. 28, 2021 (KR) 10-2021-0189930

(51) Int. Cl. G03F 1/72

(52) U.S. Cl. CPC G03F 1/72

(57) ABSTRACT

The inventive concept provides a substrate treating apparatus. The substrate treating apparatus includes a housing; a support unit positioned within the housing and configured to support a substrate; a liquid supply unit configured to supply a treating liquid to the substrate supported on the support unit; and a laser module configured to irradiate a laser to the substrate to which the treating liquid is supplied; and a vision module for monitoring a point at which the laser is irradiated among the substrate.

### CROSS-REFERENCE TO RELATED APPLICATIONS

A claim for priority under 35 U.S.C. § 119 is made to Korean Patent Application No. 10-2021-0189930 filed on Dec. 28, 2021, in the Korean Intellectual Property Office, the entire contents of which are hereby incorporated by reference.

### BACKGROUND

Embodiments of the inventive concept described herein relate to a substrate treating apparatus and a substrate treating method.

In order to manufacture a semiconductor element, various processes such as a photolithography process, an etching process, an ashing process, an ion implantation process, and a thin film deposition process are performed on a substrate such as a wafer. Various treating liquids and treating gases are used in each process. In addition, a drying process is performed on the substrate to remove a treating liquid used to treat the substrate from the substrate.

The photolithography process for forming a pattern on the wafer includes an exposing process. The exposing process is an operation which is previously performed for cutting a semiconductor integrated material attached to the wafer into a desired pattern. The exposing process may have various purposes such as forming a pattern for an etching and forming a pattern for the ion implantation. In the exposing process, the pattern is drawn in on the wafer with a light using a mask, which is a kind of ‘frame’. When the light is exposed to the semiconductor integrated material on the wafer, for example, a resist on the wafer, chemical properties of the resist change according to a pattern by the light and the mask. When a developing liquid is supplied to a resist which chemical properties have changed according to the pattern, the pattern is formed on the wafer.

In order to precisely perform the exposing process, the pattern formed on the mask must be precisely manufactured. To confirm that the pattern is formed in a desired form and precisely, an operator inspects a formed pattern using an inspection equipment such as a scanning electron microscope (SEM). However, a large number of patterns are formed on one mask. That is, it takes a lot of time as all of the large number of patterns must be inspected to inspect one mask.

Accordingly, a monitoring pattern capable of representing one pattern group including a plurality of patterns is formed on the mask. In addition, an anchor pattern that may represent a plurality of pattern groups are formed on the mask. The operator may estimate whether patterns formed on the mask are good or not through an inspecting of the anchor pattern. In addition, the operator may estimate whether patterns included in one pattern group are good or not through an inspecting of the monitoring pattern.

As described above, the operator may effectively shorten a time required for a mask inspection due to the monitoring pattern and the anchor pattern formed on the mask. However, in order to increase an accuracy of the mask inspection, it is preferable that critical dimension of the monitoring pattern and the anchor pattern are the same.

When an etching is performed to equalize the critical dimension of the monitoring pattern and the critical dimension of the anchor pattern, an over-etching may occur at the pattern. For example, a difference between an etching rate for the critical dimension of the monitoring pattern and an etching rate for the anchor pattern may occur several times, and in the process of repeatedly etching the monitoring pattern and/or the anchor pattern to reduce the difference, the over-etching may occur at the critical dimension of the monitoring pattern and the critical dimension of the anchor pattern. When the etching process is precisely performed to minimize an occurrence of such over-etching, the etching process takes a lot of time. Accordingly, a critical dimension correction process for precisely correcting the critical dimension of patterns formed on the mask is additionally performed.

FIG. 1 illustrates a normal distribution regarding a first critical dimension CDP1 of the monitoring pattern of the mask and a second critical dimension CDP2 (a critical dimension of the anchor pattern) before a critical dimension correction process is performed, which is the last step during a mask manufacturing process. In addition, the first critical dimension CDP1 and the second critical dimension CDP2 have a size smaller than a target critical dimension. Also, before the critical dimension correction process is performed, there is a deliberate deviation between the critical dimension of the monitoring pattern and the anchor pattern (CD, critical dimension) as seen in FIG. 1. And, by additionally etching the anchor pattern in the critical dimension correction process, the critical dimension of these two patterns are made the same.

In the critical dimension correction process, an etching chemical is supplied onto the substrate such that the first critical dimension CDP1 and the second critical dimension CDP2 become target critical dimensions. However, if the etching chemical is uniformly supplied on the substrate, even if either the first critical dimension CDP1 or the second critical dimension CDP2 can reach the target critical dimension, it is difficult for the other to reach the target critical dimension. Further, a deviation between the first critical dimension CDP1 and the second critical dimension CDP2 is not reduced.

Accordingly, the etching chemical is supplied to the substrate, and a region at which the anchor pattern is formed among the substrate supplied with the etching chemical is locally heated using a laser light. A temperature of a local part of a substrate surface is increased by the laser irradiated locally to an anchor pattern region, and bubbles are generated due to a vaporization phenomenon of the chemical if a temperature reaches of a boiling point or near the boiling point of the chemical. As a local heating time increases, the amount of generated bubbles increases. The bubbles generated on the substrate surface prevent the substrate surface from being in contact with the chemical, and thus, there is a problem in that an etching is not performed or an etching degree is degraded. In this case, there is a problem that the anchor pattern may not secure the first critical dimension CDP1 which was targeted.

### SUMMARY

Embodiments of the inventive concept provide a substrate treating apparatus and a substrate treating method for efficiently treating a substrate.

Embodiments of the inventive concept provide a substrate treating apparatus and a substrate treating method for making a critical dimension of a pattern formed on a substrate uniform.

Embodiments of the inventive concept provide a substrate treating apparatus and a substrate treating method for preventing an etching efficiency from decreasing due to an abnormally growing bubble in a process of irradiating a laser to a local part of a substrate.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a housing; a support unit positioned within the housing and configured to support a substrate; a liquid supply unit configured to supply a treating liquid to the substrate supported on the support unit; and a laser module configured to irradiate a laser to the substrate to which the treating liquid is supplied; and a vision module for monitoring a point at which the laser is irradiated among the substrate.

In an embodiment, a laser irradiated from the laser module and an imaging axis of the vision module are provided to be coaxial.

In an embodiment, the substrate treating apparatus includes a lighting module providing a lighting to a point at which the laser is irradiated among the substrate, and wherein a lighting axis of the lighting module and an imaging axis of the vision module are provided to be coaxial.

In an embodiment, the substrate treating apparatus further includes a lighting module providing a lighting to a point at which the laser is irradiated among the substrate, and wherein the laser module and the vision module are provided on a same plane, and the lighting module is provided below the vision module.

In an embodiment, the substrate treating apparatus further includes a body providing the laser module, the vision module and the light module therein, and wherein an irradiation end is provided at the body, and the laser of the laser module is irradiated to the substrate being coaxial with an imaging axis of the vision module, and a lighting axis of a lighting of the lighting module is configured parallel to the imaging axis of the vision module.

In an embodiment, the vision module monitors whether a bubble has been generated and whether a size of the bubble grows during a process of heating the treating liquid applied on the substrate by the laser.

In an embodiment, the substrate treating apparatus further includes a controller for controlling the substrate treating apparatus, and wherein whether a process which is being performed with respect to the substrate may be terminated is determined by comparing a reference image of the substrate acquired from the vision module and a substrate image of the substrate at which the bubble is generated which is acquired from the vision module.

In an embodiment, the controller continues a process which is proceeding on the substrate, if a change amount of the reference image and the substrate image is determined to be 10% or lower.

In an embodiment, the controller terminates a process which is proceeding on the substrate, if a change amount between the reference image and the substrate image is determined to be 10% or higher.

In an embodiment, the controller changes a process condition with respect to a substrate at which a process will be proceeded on afterward, if the process which is proceeding on the substrate is terminated, and the controller controls the laser module so an output condition of the laser is changed or an irradiation range of the laser is changed.

In an embodiment, the substrate includes a first pattern and a second pattern formed at a different position from the first pattern, and wherein the laser module irradiates the laser to any one pattern among the first pattern and the second pattern.

In an embodiment, the substrate includes a first pattern having a first critical dimension and a second pattern formed at a different position from the first pattern and which has a second critical dimension which is smaller than the first critical dimension, and wherein the laser module irradiates the laser to the second pattern so the first critical dimension and the second critical dimension become the same.

The inventive concept provides a substrate treating method. The substrate treating method includes taking in a substrate having a first pattern and a second pattern which is formed at a different position from the first pattern; correcting a critical dimension of the first pattern or the second pattern; supplying a rinsing liquid to a substrate; and taking out the substrate, and wherein at the correcting the critical dimension, whether a bubble has been generated is detected through a vision module, and if the bubble is detected, whether a critical dimension correction process is performed is determined by comparing a substrate image at which the bubble is generated and a reference image.

In an embodiment, at the correcting the critical dimension, the treating liquid is supplied to the substrate, a laser is irradiated by a laser module to the substrate to heat the substrate at which the treating liquid is applied, and the laser module irradiates the laser to the second pattern.

In an embodiment, the reference image is acquired through the vision module, and the vision module acquires the reference image through an image of a state of the substrate to which the laser is irradiated by turning on the laser module.

In an embodiment, the critical dimension correction process with respect to the substrate is continued, if a change value between a substrate image at which the bubble is generated and the reference image is 10% or lower.

In an embodiment, the critical dimension correction process with respect to the substrate is terminated, if a change value between a substrate image at which the bubble is generated and the reference image is 10% or higher.

In an embodiment, an alarm is generated if the change value is 10% or higher, and the laser module is turned off if the alarm is generated.

In an embodiment, if the change value is determined to be 10% or higher and the critical dimension correction process is terminated, a process condition with respect to a substrate to be post-treated is reset.

In an embodiment, the vision module monitors whether the bubble is generated in real time, or whether the bubble is generated in predetermined time intervals.

The inventive concept provides a substrate treating apparatus. The substrate treating apparatus includes a housing; a support unit positioned within the housing and configured to support a substrate; a liquid supply unit configured to supply a treating liquid to the substrate supported on the support unit; a heating unit configured to heat the substrate to which the treating liquid is supplied; and a controller, and wherein the heating unit includes: a body at which an irradiation end is provided; a laser module provided within the body and irradiating a laser to the substrate to heat the substrate; a vision module provided within the body for monitoring whether a bubble is generated at a point at which the laser is irradiated, and which is coaxial with the laser module; and a lighting module provided within the body and providing a lighting to the point at which the laser is irradiated, and which is coaxial with the vision module, and wherein the vision module acquires a reference image of the substrate immediately after the laser is turned on at the laser module, and acquires a substrate image at which the bubble is generated if the bubble is generated, and the controller determines whether to continue proceeding with the process by comparing the reference image and the substrate image at which the bubble is generated, and terminates the process if a compare value is 10% or higher.

According to an embodiment of the inventive concept, a substrate may be efficiently treated.

According to an embodiment of the inventive concept, a critical dimension of a pattern formed on a substrate may be made uniform.

According to an embodiment of the inventive concept, a decrease of an etching efficiency caused by an abnormally growing bubble in a process of irradiating a laser to a local part of a substrate may be prevented.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a normal distribution of a critical dimension of a monitoring pattern and a critical dimension of an anchor pattern.

FIG. 2 is a plan view schematically illustrating a substrate treating facility according to an embodiment of the inventive concept.

FIG. 3 schematically illustrates a state of a substrate treated at a liquid treating chamber of FIG. 2.

FIG. 4 schematically illustrates an embodiment of the liquid treating chamber of FIG. 2.

FIG. 5 is a top view of the liquid treating chamber of FIG. 4.

FIG. 6 is a side cross-sectional view of a heating unit of FIG. 4.

FIG. 7 is a plan view of the heating unit of FIG. 4.

FIG. 8 schematically illustrates a laser module, a vision module, a lighting module, and an optical member provided within the heating unit of FIG. 4.

FIG. 9 is a flowchart of a substrate treating method according to an embodiment of the inventive concept.

FIG. 10 is a flowchart illustrating a critical dimension correction step of FIG. 9.

FIG. 11 illustrates a state of a substrate treating apparatus performing a treating liquid supply step of FIG. 10.

FIG. 12 illustrates the substrate treating apparatus performing a reference image acquiring step of FIG. 10.

FIG. 13 illustrates an embodiment of the reference image acquired in FIG. 12.

FIG. 14 illustrates a state of the substrate treatment apparatus performing a heat treating step of FIG. 10.

FIG. 15 illustrates an embodiment of a substrate image in which bubbles acquired by the vision module are generated if bubbles are generated in the heating treating process of FIG. 14.

FIG. 16 illustrates the substrate treating apparatus performing a rinsing step of FIG. 9.

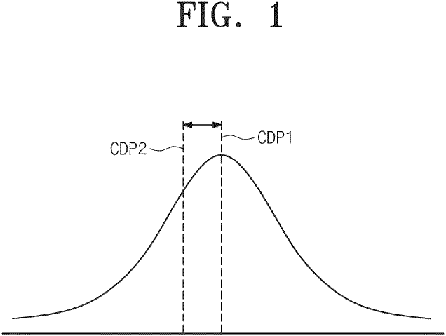

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises”, “comprising,”, “includes”, and/or “including” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “example” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Other terms such as “between”, “adjacent”, “near” or the like should be interpreted in the same way.

Unless otherwise defined, all terms used herein, including technical or scientific terms, have the same meaning as those generally understood by those skilled in the art to which the inventive concept belongs. Terms such as those defined in commonly used dictionaries should be interpreted as consistent with the context of the relevant technology and not as ideal or excessively formal unless clearly defined in this application.

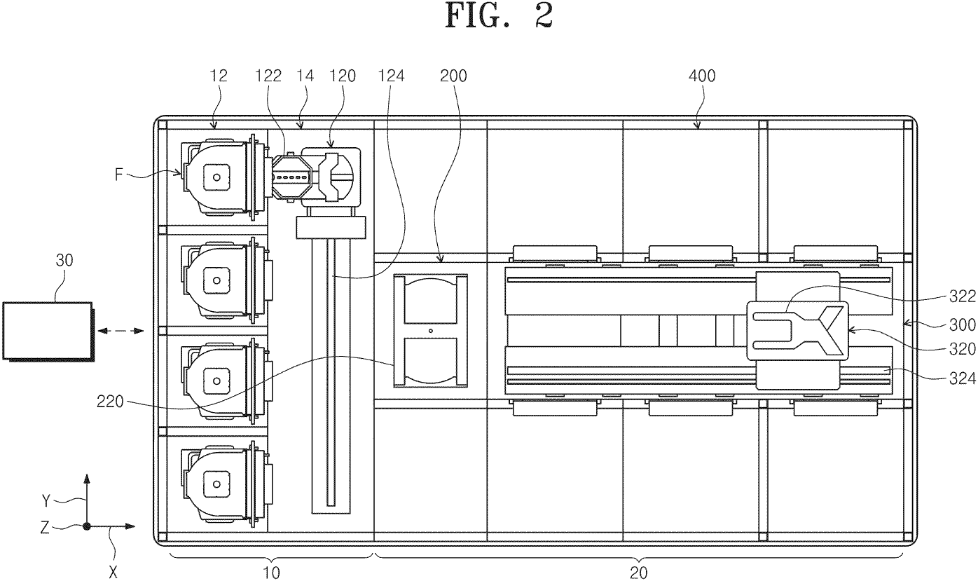

Hereinafter, an embodiment of the inventive concept will be described in detail with reference to FIG. 2 to FIG. 16.

FIG. 2 is a plan view schematically illustrating a substrate treating facility according to an embodiment of the inventive concept.

Referring to FIG. 2, the substrate treating apparatus 1 may include an index module 10, a treating module 20, and a controller 30. According to an embodiment, when viewed from above, the index module 10 and the treating module 20 may be disposed along a direction.

Hereinafter, a direction in which the index module 10 and the treating module 20 are disposed is defined as a first direction X, a direction perpendicular to the first direction X when viewed from the front is defined as a second direction Y, and a direction perpendicular to a plane including both the first direction X and the second direction Y is defined as a third direction Z.

The index module 10 may transfer a substrate M from a container F in which the substrate M is accommodated to the treating module 20 for treating the substrate M. The index module 10 may store a substrate M on which a predetermined treatment has been completed at the treating module 20 in the container F. A lengthwise direction of the index module 10 may be formed in the second direction Y. The index module 10 may have a load port 12 and an index frame 14.

The container F in which the substrate M is accommodated may be seated on the load port 12. The load port 12 may be positioned on an opposite side of the treating module 20 with respect to the index frame 14. A plurality of load ports 12 may be provided, and the plurality of load ports 12 may be arranged in a line along the second direction Y. The number of load ports 12 may increase or decrease according to a process efficiency and foot print conditions, etc of the treating module 20.

As the container F, a sealing container such as a front opening unified pod (FOUP) may be used. The container F may be placed on the load port 12 by a transfer means (not shown) such as an overhead transfer, an overhead conveyor, or an automatic guided vehicle, or by an operator.

An index frame 14 may provide a transfer space for transferring the substrate M. An index robot 120 and an index rail 124 may be provided at the index frame 14. The index robot 120 may transfer the substrate M. The index robot 120 may transfer the substrate M between the index module 10 and the buffer unit 200 to be described later. The index robot 120 includes an index hand 122. The substrate M may be placed on the index hand 122. The index hand 122 may grip or support the substrate M while the substrate M is transferred. The index hand 122 may be provided to be forwardly and backwardly movable, rotatable in the third direction Z, and movable along the third direction Z. A plurality of index hands 122 may be provided. Each of the plurality of index hands 122 may be provided to be spaced apart from each other in an up/down direction. The plurality of index hands 122 may be forwardly and backwardly movable independently of each other.

The index rail 124 is provided within the index frame 14. The index rail 124 may be provided with its lengthwise direction corresponding to a lengthwise direction of the index frame 14. The index rail 124 may be provided with its lengthwise direction along the second direction Y. The index robot 120 may be placed on the index rail 124, and the index robot 120 may be movable along the index rail 124. The index robot 120 may be provided to be linearly movable along the index rail 124.

The controller 30 may control a substrate treating apparatus 1. The controller may comprise a process controller consisting of a microprocessor (computer) that executes a control of the substrate treating apparatus 1, a user interface such as a keyboard via which an operator inputs commands to manage the substrate treating apparatus, and a display showing the operation situation of the substrate treating apparatus 1, and a memory unit storing a treating recipe, i.e., a control program to execute treating processes of the substrate treating apparatus 1 by controlling the process controller or a program to execute components of the substrate treating apparatus 1 according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

The controller may control the substrate treating apparatus 1 and/or the liquid treating chamber 400 so the substrate treating method to be described later may be performed. For example, the controller 30 may control the configuration provided in the liquid treating chamber 400 to perform the substrate treating method to be described later.

The treating module 20 may include a buffer unit 200, a transfer frame 300, and a liquid treating chamber 400. The buffer unit 200 may provide a space in which a substrate M taken into the treating module 20 and a substrate M taken out of the treating module 20 temporarily remain. The transfer frame 300 may provide a space for transferring the substrate M between the buffer unit 200 and the liquid treating chamber 400. The liquid treating chamber 400 may perform a liquid treating process of supplying a liquid onto the substrate M. The treating module 20 may further include a drying chamber, and the drying chamber may perform a drying process of drying the substrate M on which a liquid treatment has been completed.

The buffer unit 200 may be disposed between the index frame 14 and the transfer frame 300. The buffer unit 200 may be positioned at an end of the transfer frame 300. The buffer unit 200 may store a plurality of substrates within. A slot (not shown) in which the substrate M is placed may be provided inside the buffer unit 200. A plurality of slots (not shown) may be provided. The plurality of slots (not shown) may be provided to be spaced apart from each other in the third direction Z. Accordingly, a plurality of substrates M stored in the buffer unit 200 may be spaced apart from each other in the third direction Z.

A front face and a rear face of the buffer unit 200 may be opened. The front face is a surface facing the index module 10, and the rear face is a surface facing the transfer frame 300. The index robot 120 may approach the buffer unit 200 through the front face, and the transfer robot 320 to be described later may approach the buffer unit 200 through the rear face.

The transfer frame 300 may have a lengthwise direction provided in the first direction X. The liquid treating chamber 400 may be disposed on both sides of the transfer frame 300. The liquid treating chamber 400 and the drying chamber 500 may be disposed at a side of the transfer frame 300. The transfer frame 300 and the liquid treating chamber 400 may be disposed along the second direction Y. The transfer frame 300 and the drying chamber 500 may be disposed along the second direction Y. At a side or at each side of the transfer frame 300, the liquid treating chambers 400 may be provided in an arrangement of AX B (where A and B are natural numbers greater than 1 or 1 respectively) along the first direction X and the third direction Z respectively. At the other side of the transfer frame 300, the drying chambers may be provided in an arrangement of AX B (where A and B are natural numbers greater than 1 or 1 respectively) along the first direction X and the third direction Z respectively.

The transfer frame 300 may include a transfer robot 320 and a transfer rail 342. The transfer robot 320 transfers the substrate M. The transfer robot 320 may transfer the substrate M between the buffer unit 200 and the liquid treating chamber 400. Also, transfer robot 320 may transfer the substrate M between the buffer unit 200, the liquid treating chamber 400, and the drying chamber. The transfer robot 320 may include a transfer hand 322 on which the substrate M is placed. The substrate M may be placed on the transfer hand 322. The transfer hand 322 may be provided to be forwardly and backwardly movable, to be rotatable around the third direction Z, and movable along the third direction Z. A plurality of hands 322 are provided to be spaced apart from each other in the up/down direction, and the plurality of hands 322 may be forwardly and backwardly movable independently of each other.

The transfer rail 324 may be provided in the transfer frame 300 along a lengthwise direction of the transfer frame 300. In an embodiment, the lengthwise direction of the transfer rail 324 may be provided along the first direction X. The transfer robot 320 may be placed on the transfer rail 324 and the transfer robot 320 may be movable on the transfer rail 340.

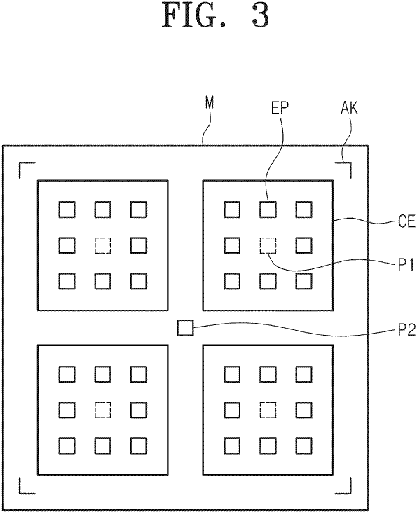

FIG. 3 schematically illustrates a state of the substrate treated in the liquid treating chamber of FIG. 2. Hereinafter, a substrate M treated in the liquid treating chamber 400 according to an embodiment of the inventive concept will be illustrated referring to FIG. 3.

Referring to FIG. 3, an object to be treated in the liquid treating chamber 400 may be any one of a wafer, a glass, and a photomask. For example, the substrate M treated in the liquid treating chamber 400 in an embodiment of the inventive concept may be a photo mask, which is a ‘frame’ used in an exposing process.

The substrate M may have a rectangular form. The substrate M may be a photo mask that is a ‘frame’ used in the exposing process. At least one reference mark AK may be marked on the substrate M. For example, a plurality of reference marks AK may be formed in each corner region of the substrate M. The reference mark AK may be a mark called an align key used when aligning the substrate M. Also, the reference mark AK may be a mark used to derive a position of the substrate M. For example, a vision module 470 to be described later may acquire an image by imaging the reference mark AK and transmit the acquired image to the controller 30. The controller 30 then may analyze the image including the reference mark AK to detect an accurate position of the substrate M. In addition, the reference mark AK may be used to determine a position of the substrate M when the substrate M is transferred.

A cell CE may be formed on the substrate M. At least one cell CE, for example, a plurality of cells CE may be formed. A plurality of patterns may be formed at each cell CE. The patterns formed at each cell CE may be defined as one pattern group. Patterns formed at the cell CE may include an exposing pattern EP and a first pattern P1. The exposing pattern EP may be used to form an actual pattern on the substrate M. The first pattern P1 may be provided within the cell CE. The first pattern P1 may be a single-cell representative pattern representing exposing patterns EP in one cell CE. In addition, when the plurality of cells CE are provided, the first pattern is provided in each cell, thereby a plurality of first patterns P1 may be provided. Also, the plurality of first patterns P1 may be formed in one cell CE. The first pattern P1 may have a form in which portions of each exposing pattern EP are combined. The first pattern P1 may be referred to as a monitoring pattern. Also, the first pattern P1 may be referred to as a critical dimension monitoring macro.

When an operator inspects the first pattern P1 through a scanning electron microscope (SEM), it is possible to estimate whether a form of the exposing patterns EPs formed in one cell CE are good or bad. Also, the first pattern P1 may serve as an inspection pattern to inspect the exposing patters EPs. Also, the first pattern P1 may be any one of the exposing patterns EPs used in an actual exposing process. In addition, the first pattern P1 may be serve as not only inspection pattern to inspect the exposing patterns but also exposing pattern used in the actual exposing.

The second pattern P2 may be an entire-cell representative pattern representing exposing patterns EP on whole cells of the substrate M. For example, the second pattern P2 may have a form in which portions of each of the first patterns P1 are combined.

When the operator inspects the second pattern P2 through the scanning electron microscope (SEM), it is possible to estimate whether a form of the exposing patterns EPs formed on one substrate M are good or bad. Also, the second pattern P2 may serve an inspection pattern. In addition, the second pattern P2 may be an inspection pattern that is not used in an actual exposing process. The second pattern P2 may be referred to as an anchor pattern.

Hereinafter, the substrate treating apparatus provided to the liquid treating chamber 400 will be described in detail. Hereinafter, a treating process performed while the liquid treating chamber 400 performs a fine critical dimension correction (FCC) process which is the last step during a process of manufacturing a mask for an exposing process will be described as an example.

A substrate M to be taken in and treated at the liquid treating chamber 400 may be a substrate M on which a pre-treatment has been performed. A critical dimension of the first pattern P1 and a critical dimension of the second pattern P2 of the substrate M to be taken into the liquid treating chamber 400 may be different from each other. The first pattern P1 may have a critical dimension of a first width, and the second pattern P2 may have a critical dimension of a second width. For example, the first pattern may be bigger than the second pattern. For example, the first width may be 69 nm and the second width may be 68.5 nm.

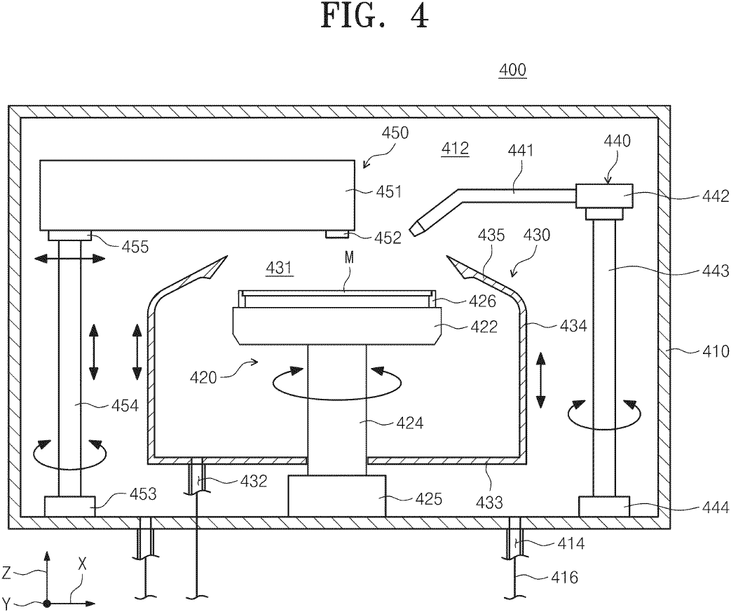

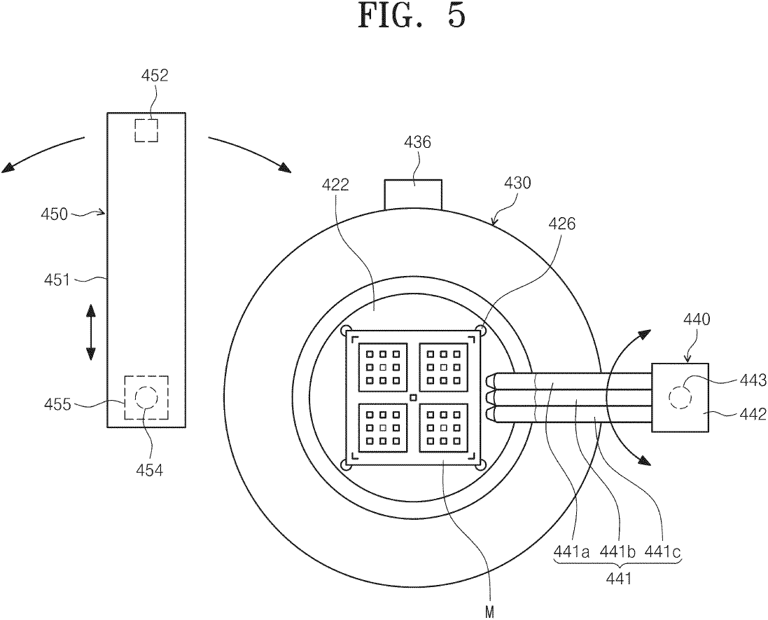

FIG. 4 schematically illustrates an embodiment of the liquid treating chamber of FIG. 2, and FIG. 5 is a top view of the liquid treating chamber of FIG. 4.

Referring to FIG. 4 and FIG. 5, the liquid treating chamber 400 may include a housing 410.

The housing (not shown) may have an inner space 412. The housing 412 may a bowl 320 to be described later at the inner space 412. A liquid supply unit 440 and a heating unit 450 to be described later may be provided at the inner space of the housing 412. The housing 412 may be provided with a gateway (not shown) through which the substrate M may be taken in and taken out. The gateway may be selectively opened and closed by a door (not shown). An inner wall surface of the housing 412 may be coated with a material having a high corrosion resistance to a chemical supplied by the liquid supply unit 440.

An exhaust hole 414 may be formed on a bottom surface of the housing 414. An exhaust line 416 may be connected at the exhaust hole 414. An exhaust member (not shown) such as a pump which can exhaust the inner space 414 may be installed at the exhaust line 416. Accordingly, contaminants such as a fume or particles which may be generated in the inner space 412 may be exhausted to an outside through the exhaust hole 414.

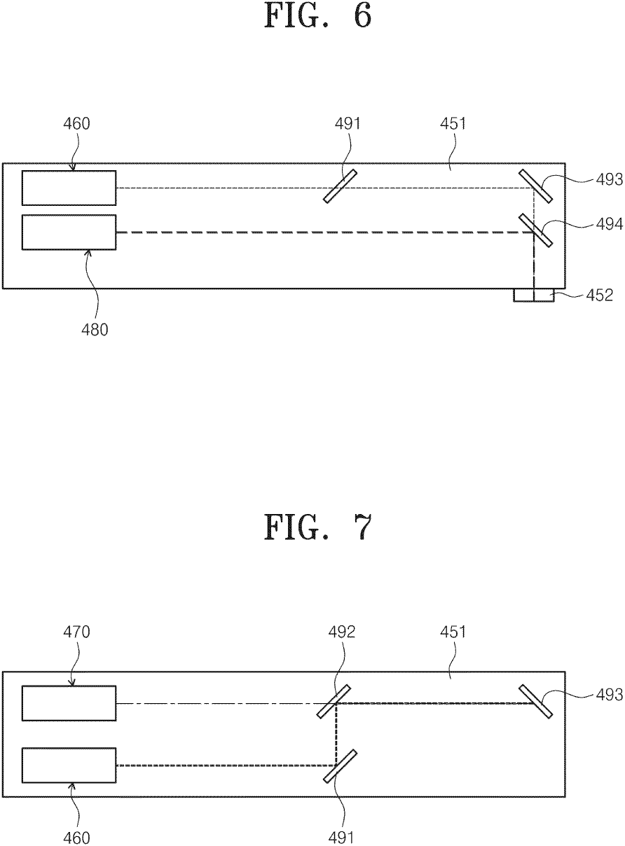

According to FIG. 6 and FIG. 6, the liquid treating chamber 400 may include a support unit 420. The support unit 420 may support the substrate M in a treating space 431 of a bowl 430 to be described later. The support unit 420 may support the substrate M. The support unit 420 may rotate the substrate M.

The support unit 420 may include a chuck 422, a support shaft 424, a driving member 425, and a support pin 426. The chuck 422 may have a plate shape having a predetermined thickness. The support shaft 424 may be coupled to a bottom portion of the chuck 422. The support shaft 424 may be a hollow shaft. Also, the support shaft 424 may be rotated by the driving member 425. The driving member may be a hollow motor. If the driving member 425 rotates the support shaft 424, the chuck 422 coupled to the support shaft 424 may be rotated. A substrate M placed on the support pin 426 installed at the chuck 422 may rotate together with a rotation of the chuck 422.

The support pin 426 may support the substrate M. The support pin 426 may be installed at the chuck 422. The support pin 426 may protrude from a top surface of the chuck 422. When viewed from above, the support pin 422 may have a substantially circular form. Also, when viewed from above, a portion of the support pin 426 which corresponds to an edge region of the substrate M may be downwardly stepped. That is, the support pin 426 may include a first surface which supports a bottom portion of an edge region of the substrate M, and a second surface facing a side of an edge region of the substrate M so as to limit a lateral movement of the substrate M if the substrate M is rotated. At least one support pin 422 may be provided. In an embodiment, a plurality of support pins 422 may be provided. The support pin 422 may be provided in a number corresponding to the number of edge regions of the substrate M having a rectangular form. The support pin 422 may support the substrate M to space apart the bottom surface of the substrate M from the top surface of the chuck 422.

Referring to FIG. 5 and FIG. 6, the liquid treating chamber 400 may include a bowl 430.

The bowl 430 may have a cylindrical form with an open top. The bowl 430 may have a treating space 431, and the substrate M may be liquid-treated and heat-treated in the treating space 431. The bowl 430 can prevent the treating liquid supplied to the substrate M from being scattered to the housing 410, the liquid supply unit 440, and the heating unit 450.

The bowl 430 may include a bottom portion 433, a vertical portion 434, and an inclined portion 435. The bottom portion 433 may be provided with an opening which may be inserted into the support shaft 424 when seen from above. The vertical portion 434 may extend in the third direction Z from the bottom portion 433. The inclined portion 435 may extend in a direction of the support unit 420 from a top end of the vertical portion 434. The inclined portion 435 may be extend from the top end of the vertical portion 323 to the support unit 420 in an upwardly inclined direction. The inclined portion 435 may be extend inclined in a direction toward the substrate M supported on the support unit 420. The bottom portion 433 may have a discharge hole 432 formed for discharging the treating liquid supplied from the liquid supply unit 440 to on outside.

The bowl 430 may be coupled to a lifting/lowering member 436. The bowl 430 may have its position changed along the third direction Z according to the lifting/lowering member 436. The lifting/lowering member 436 may be a driving device for moving the bowl 430 in the up/down direction. The lifting/lowering member 436 may move the bowl 430 in an upward direction while a liquid treatment and/or a heat treatment are performed on the substrate M. The lifting/lowering member 436 may move the bowl 430 in a downward direction when the substrate M is taken into the inner space or the substrate M is taken out of the inner space.

Referring to FIG. 5 and FIG. 6, the liquid treating chamber 400 may include a liquid treating unit 440. The liquid supply unit 440 may supply a liquid to the substrate M. The liquid supply unit 440 may supply a treating liquid for liquid treating the substrate M. The liquid supply unit 440 may supply the treating liquid to a substrate M supported by the support unit 420.

The treating liquid may be an etching liquid or a rinsing liquid. The etching liquid may be a chemical. The etching liquid may etch a pattern formed on the substrate M. The etching liquid may also be referred to as an etching liquid. The rinsing liquid may clean the substrate M. The rinsing liquid may be provided as a known chemical liquid.

The liquid supply unit 440 may include a nozzle 441, a fixing body 442, a rotation shaft 443, and a rotation member 444. The nozzle 441 may supply the treating liquid to the substrate M supported by the support unit 420. An end of the nozzle 441 may be connected to the fixing body 442, and another end thereof may extend in a direction from the fixing body 442 toward the substrate M. The nozzle 441 may extend along the first direction X from the fixing body 442. Also, the other end of the nozzle may be cut out in a predetermined angle and may extend toward the substrate M supported on the support unit 420.

The nozzle 441 may include a first nozzle 441a, a second nozzle 441b, and a third nozzle 441c. Any one of the first nozzle 441a, the second nozzle 441b, or the third nozzle 441c may supply a chemical C among the above-described treating liquids to the substrate M. In addition, another one of the first nozzle 441a, the second nozzle 441b, and the third nozzle 441c may supply the rinsing liquid R among the aforementioned treating liquids. Also, the last one of the first nozzle 441a, the second nozzle 441b, or the third nozzle 441c may supply a different kind of chemical C which is different from a chemical C supplied by the another one of the first nozzle 441a, the second nozzle 441b, or the third nozzle 441c.

A fixing body 442 may a fix the nozzle 441. The fixing body 442 may support the nozzle 441.The fixing body 442 may be connected to the rotation shaft 443 rotated in the third direction Z by the rotation member 444. If the rotation member 444 rotates the rotation shaft 443, the fixing body 442 may rotate around the third direction Z. Accordingly, an outlet of the nozzle 441 may move between a liquid supply position which is a position where the treating liquid is supplied to the substrate M and a standby position which is a position where the treating liquid is not supplied to the substrate M. The outlet of the nozzle 441 may be swing moved between the liquid supply position and the standby position.

Referring to FIG. 5 and FIG. 6, the liquid treating chamber 400 may include the treating unit 450.

The heating unit 450 may heat the substrate M. The heating unit 450 may heat a partial region of the substrate M. The heating unit 450 may heat the substrate M on which a liquid film is formed by supplying the chemical C. The heating unit 450 may heat a pattern formed on the substrate M. The heating unit 450 may heat some of the patterns formed on the substrate M. The heating unit 450 may heat any one of the first pattern P1 or the second pattern P2. For example, the heating unit 450 may heat the second pattern P2 among the first pattern P1 and the second pattern P2.

The heating unit 450 may include a body 451. The body 451 may be a container having an installation space therein. The body 451 may be provided with a laser irradiation module 460 to be described later, a vision module 470, a lighting module 480, and an optical member 490. Also, the body 451 may include an irradiation end 452. The laser L irradiated by the laser irradiation module 460 to be described later may be irradiated to the substrate M through the irradiation end 452. In addition, a light irradiated by the lighting module 480 to be described later may be provided through the irradiation end 452. In addition, an imaging of a vision module 470 to be described later may be performed through the irradiation end 452.

The heating unit 450 may include a driver 453. The driver 453 may be a motor. The driver 453 may be connected to a shaft 454 to be described later. The driver 453 may rotate the shaft 454. The driver 453 may provide a power to the shaft 454 to rotate the shaft 454. Accordingly, the body 451 coupled to the shaft 454 is rotated, and a position of an irradiation end 452 of the body 451 may also be changed. The driver 453 may move the shaft 454 in a vertical direction. For example, the position of the irradiation end 452 may be changed with the third direction Z as a rotation axis. When viewed from above, the center of the irradiation end 452 may be moved while drawing an arc around the shaft 454. When viewed from above, the irradiation end 452 may be moved such that the center thereof passes through the center of the substrate M supported by the support unit 420. The irradiation end 452 may move between a heating position to irradiate the laser L with the substrate M and a standby position, which is a standby position when a heating the substrate M is not performed. In addition, the driver 453 may move the shaft 454 in an up/down direction. The driver 453 may provide a power to the shaft 454 so that the shaft 454 moves in an up/down direction. Accordingly, the body 451 coupled to the shaft 454 is moved in the up/down direction, and the position of the irradiation end 452 of the body 451 may be changed in the up/down direction. A plurality of drivers 453 may be provided. Any one of the plurality of drivers 453 may be provided as a rotation motor for rotating the shaft 454. The other of the plurality of drivers 453 may be provided as a linear motor for moving the shaft 454 in the up/down direction.

The heating unit 450 may include the shaft 454. The shaft 454 may be coupled to the body 451. The shaft 454 may be connected to the body 451 via a moving member 455 to be described later. The shaft 454 may be coupled to the driver 453. The shaft 454 may be provided between the body 451 and the driver 453. The shaft 454 may be rotated or moved in an up/down direction by receiving the power from the driver 453. Accordingly, the body 451 coupled to the shaft 454 may also be rotated, swing-moved, or moved in an up/down direction. In this case, the position of the irradiation end 452 of the body 451 may be changed.

The heating unit 450 may include the moving member 455. The moving member 455 may be provided between the body 451 and the shaft 454. The moving member 455 may be an LM guide. The moving member 455 may move the body 451 in a lateral direction. The moving member 455 may move the body 451 in the first direction X and/or the second direction Y. The position of the irradiation end 452 of the heating unit 450 may be variously changed by the moving member 455 and the driver 453.

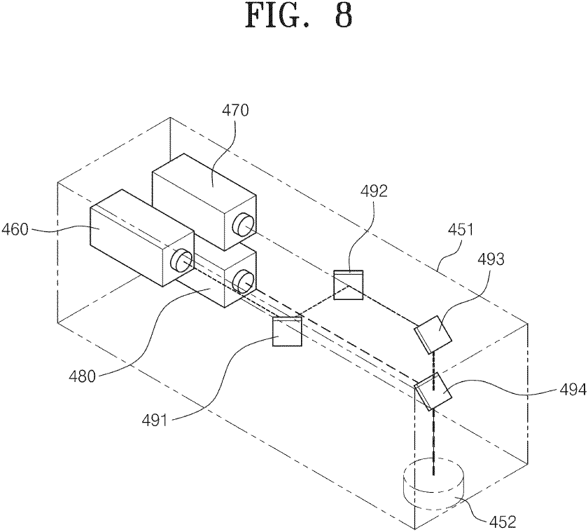

FIG. 6 is a side cross-sectional view of the heating unit of FIG. 4, FIG. 7 is a plan view of the heating unit of FIG. 4, and FIG. 8 schematically illustrates a laser module, a vision module, a lighting module, and an optical member provided within the heating unit of FIG. 4.

Referring to FIG. 6 to FIG. 8, the heating unit 450 may include a laser module 460. The laser module 460 may irradiate the laser L. The laser module 460 may irradiate the laser L having a straightness. A shape and/or profile of the laser L irradiated from the laser module 460 may be adjusted in a beam expander which is not shown. For example, a diameter of the laser L irradiated by the laser module 460 may be changed in the beam expander. The diameter of the laser L irradiated by the laser module 460 may be expanded or reduced in the beam expander.

The path of the laser L irradiated from the laser module 460 may be changed by an optical member 490 to be described later. An irradiation direction of the laser L irradiated from the laser module 460 may be changed by a first reflective member 491 to be described later. The irradiation direction of the laser L irradiated from the laser module 460 may be changed by a second reflective member 492 to be described later. The irradiation direction of the laser L irradiated from the laser module 460 may be changed by a third reflective member 493 to be described later. The laser L irradiated from the laser module 460 may proceed in a first irradiation direction. The path of the laser L irradiated from the laser module 460 and proceeding in the first irradiation direction may be changed to a second irradiation direction perpendicular to the first irradiation direction by the first reflective member 491. The laser L in the second irradiation direction may be changed to a third irradiation direction perpendicular to the second irradiation direction and parallel to the first irradiation direction by the second reflective member 492. The third irradiation direction may be a direction coaxial with an imaging direction of the vision module 470 to be described later. A path of the laser L proceeding in the third irradiation direction may be changed in a fourth irradiation direction which is downwardly perpendicular to the third irradiation direction by the third reflective member 493. The fourth irradiation direction may be a direction perpendicular to a virtual plane formed by the first irradiation direction and the second irradiation direction. The fourth irradiation direction may be a direction perpendicular to a virtual plane formed by the second irradiation direction and the third irradiation direction. The laser L traveling in the fourth irradiation direction may pass through the irradiation end 452 and be irradiated to the substrate M.

The laser module 460 may be provided within the body 451. The laser module 460 may be provided next to the vision module 470 to be described later. The laser module 460 may overlap at least a portion of the vision module 470 in the second irradiation direction. The laser module 460 may be spaced apart from the vision module 470 in the second irradiation direction. The laser module 460 may be provided at a position higher than the lighting module 480 to be described later.

The laser L irradiated from the laser module 460 may be irradiated to the substrate M coaxially with the imaging axis of the vision module 470. Through this, the vision module 470 can monitor a process of heating the substrate M and/or the substrate M to which the treating liquid is applied by the laser L irradiated from the laser module 460. The laser L irradiated from the laser module 460 may be coaxial with the imaging axis of the vision module 470 through the optical member 490. The imaging axis of the laser L irradiated from the laser module 460 and the vision module 470 may be positioned on the same plane.

Referring to FIG. 6 to FIG. 8, the heating unit 450 may include a vision module 470. The vision module 470 may monitor the laser L emitted by the laser module 460. The vision module 470 may acquire an image of the substrate M. The imaging axis of the vision module 470 may be provided coaxially with the axis of the laser L of the laser module 460. The imaging axis of the vision module 470 may pass through the irradiation end 452 coaxially with the axis of the laser L of the laser module 460. Accordingly, the vision module 470 may acquire an image of the substrate M to which the laser L of the laser module 460 is irradiated. The vision module 470 may acquire then image including a point at which the laser L irradiated by the laser module 460 is irradiated. The vision module 47 may be a camera or a vision.

A proceeding direction of the imaging axis generated in the vision module 470 may be the same as the third irradiation direction of the laser L described above (hereinafter, referred to as the first proceeding direction). The imaging axis generated by the vision module 470 may be directed toward the third reflective member 493 together with the laser L whose irradiation direction is changed by the first and second reflective members 491 and 492. The proceeding direction of the imaging axis generated in the vision module 470 may be changed by the third reflective member 493. The imaging axis generated by the vision module 470 may be changed in the second proceeding direction perpendicular to the first proceeding direction by the third reflective member 493. In this case, the second proceeding direction may be the same as the fourth irradiation direction of the laser L. The imaging axis of the vision module 470 proceeds in the second proceeding direction, passes through the irradiation end 452 to the substrate M, and acquires an image of the laser L and an irradiated point.

The vision module 470 may be provided within the body 451. The vision module 470 may be provided next to the laser module 460. The vision module 470 may be spaced apart from the laser module 460 in the second irradiation direction of the laser L. At least a portion of the vision module 470 may overlap the laser module 460 in the second irradiation direction. The vision module 470 may be provided on the lighting module 480 to be described later. The imaging axis of the vision module 470 may be parallel to the lighting axis of the lighting module 480. The imaging axis of the vision module 470 may overlap the optical axis of the lighting module 480 in a perpendicular direction (the fourth irradiation direction of the laser L or the second proceeding direction of the imaging axis). The imaging axis of the vision module 470 may be positioned on the same plane as the laser L. Accordingly, if a path of the laser L is changed by the first reflective member 491, the laser L may be irradiated toward the imaging axis of the vision module 470. In addition, if the path is changed by the laser L and the first and second reflective members 491 and 492, the laser L and the vision module 470 may be coaxial with the imaging axis, and accordingly, the laser L and the imaging axis may be irradiated to the substrate M together, and the vision module 470 may monitor the laser L and a point irradiated to on the substrate M.

Referring to FIG. 6 to FIG. 8, the heating unit 450 may include a lighting module 480. The lighting module 480 may provide a lighting so that an image acquisition of the vision module 470 may be easily performed. The lighting module 480 may be provided within the body 451. The lighting module 480 may be provided below the vision module 470. The lighting module 480 may overlap the vision module 470 in a vertical direction. An optical axis of the lighting provided by the lighting module 480 may be parallel to an imaging axis of the vision module 470. The optical axis of the lighting provided by the lighting module 480 may be parallel to the first proceeding direction of the imaging axis of the vision module 470. A path of the lighting provided by the lighting module 480 may be changed by the fourth reflective member 494. The path of the lighting provided by the lighting module 480 may be changed in a direction perpendicular to a direction in which the fourth reflective member 494 travels. The optical axis of the lighting which path is changed by the fourth reflective member 494 may be the same as the fourth irradiation direction of the laser L and the second proceeding direction of the imaging axis. As the lighting of the lighting module 480 passes through the irradiation end 452 together with the imaging axis of the vision module 470 and the laser L of the laser module 460 to the substrate M, the vision module 470 can acquire the image of the substrate M and monitor the substrate M.

Referring to FIG. 6 to FIG. 8, the heating unit 450 may include an optical module 490. The optical module 490 may be provided within the body 451. The optical module 490 may change each path such that the laser L, the imaging axis, and the lighting optical axis have a coaxial axis. The optical module 490 may include a first reflective member 491, a second reflective member 492, a third reflective member 493, and a fourth reflective member 494.

The first reflective member 491 may be installed on the path of the laser L in the first irradiation direction. The first reflective member 491 may change the path of the laser L traveling in the first irradiation direction. The first reflective member 491 may change the laser L from the first irradiation direction to the second irradiation direction perpendicular to the first irradiation direction.

The second reflective member 492 may overlap the first reflective member 491 in the second irradiation direction. The second reflective member 492 may be installed on a first proceeding direction path of the imaging axis of the vision module 470. The second reflective member 492 may change the irradiation direction of the laser L irradiated in the second irradiation direction by the first reflective member 491. The second reflective member 492 may change the laser L in the second irradiation direction to the third irradiation direction perpendicular to the second irradiation direction and parallel to the second irradiation direction. The second reflective member 492 may change the laser L traveling in the second irradiation direction in the same direction as the first proceeding direction of the imaging axis of the vision module 470.

The third reflective member 493 may be installed on the first proceeding direction path of the imaging axis of the vision module 470. The third reflective member 493 may be spaced apart from the second reflective member 492 in the first proceeding direction. The third reflective member 493 may change the laser L traveling in the third irradiation direction to the fourth irradiation direction. The third reflective member 493 may change the imaging axis moving in the first proceeding direction to the second proceeding direction.

The fourth reflective member 494 may be installed on a path on which the lighting of the lighting module 480 travels. The fourth reflective member 494 may be disposed to be spaced apart from the third reflective member 493 in a second proceeding direction and/or a fourth irradiation direction. The fourth reflective member 494 may be disposed under the third reflective member 493. The fourth reflective member 494 may change the path of the lighting. The fourth reflective member 494 may change the path so that the lighting irradiated from the lighting module 480 is irradiated in the same direction as the second proceeding direction and the fourth irradiation direction.

The third reflective member 493 and the fourth reflective member 494 may overlap the irradiation end 452 in a vertical direction.

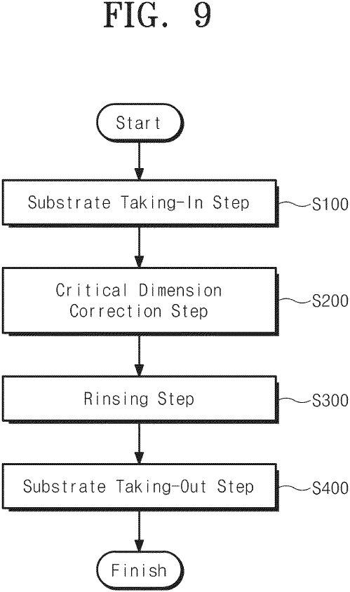

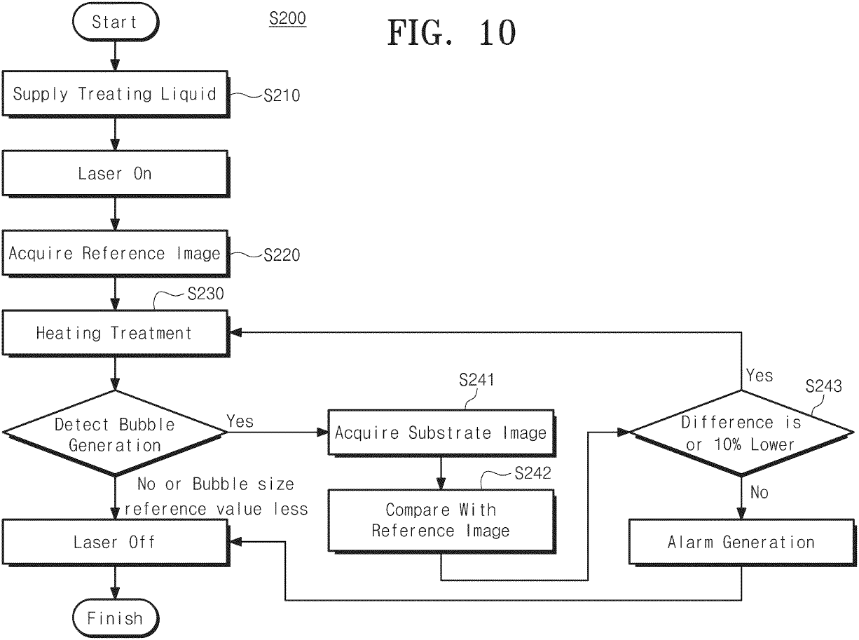

FIG. 9 schematically illustrates a basic image acquired by the vision module according to an embodiment of the inventive concept, and FIG. 10 schematically illustrates a substrate image acquired by the vision module according to an embodiment of the inventive concept. From FIGS. 10(a) to 10(d), it may be seen that bubbles are generated when a local heating time increases, and as the heating time increases, the size of the bubbles B increases.

Hereinafter, a substrate treating method according to an embodiment of the inventive concept will be described in detail with reference to the drawings. The substrate treating method according to an embodiment of the inventive concept may be performed in the above-described liquid treating chamber 400. In addition, the controller 30 can control the components of the liquid treating chamber 400 so that the liquid treating chamber 400 can perform the substrate treating method described below. For example, the controller 30 may generate a control signal that controls at least one of the support unit 420, the lifting/lowering member 436, the liquid supply unit 440, and the heating unit 450 so that the components of the liquid treating chamber 400 may perform the substrate treating method described below.

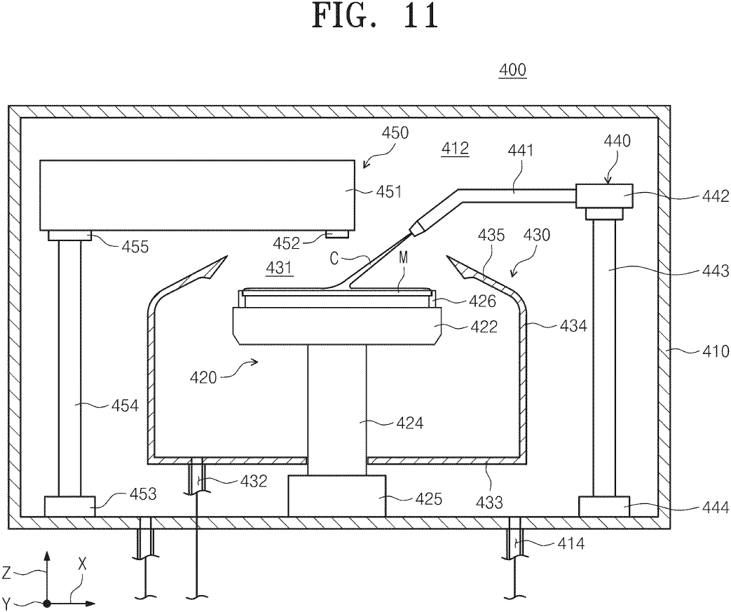

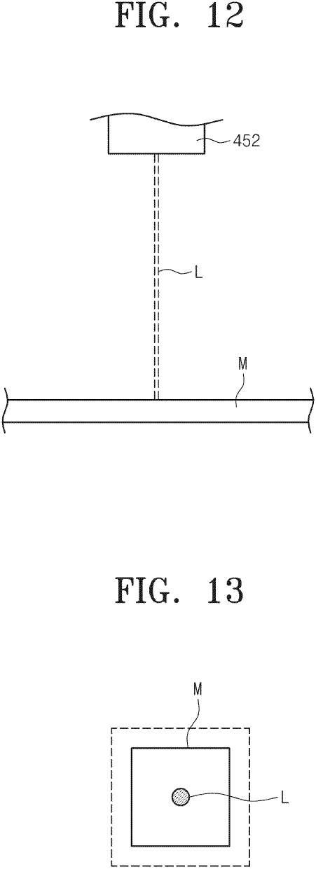

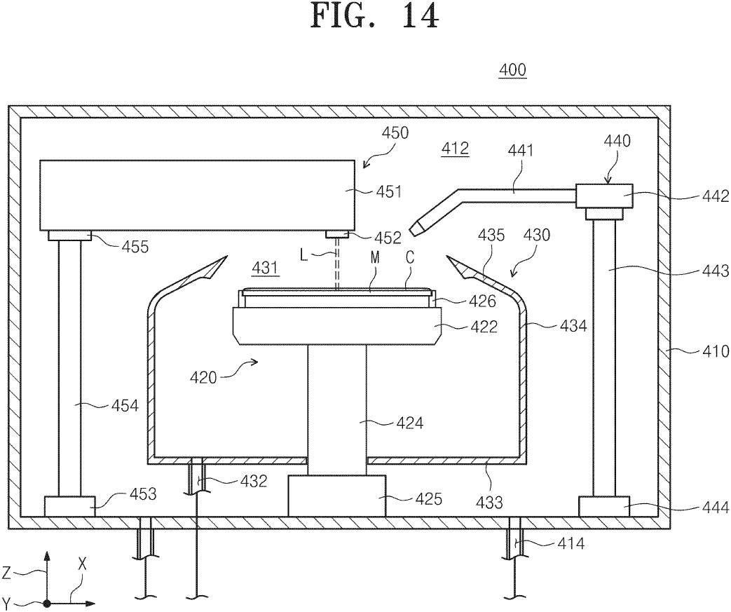

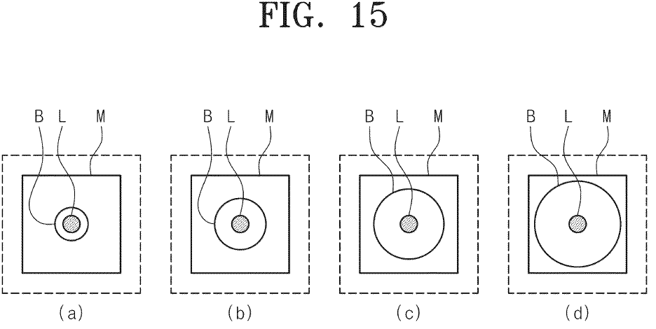

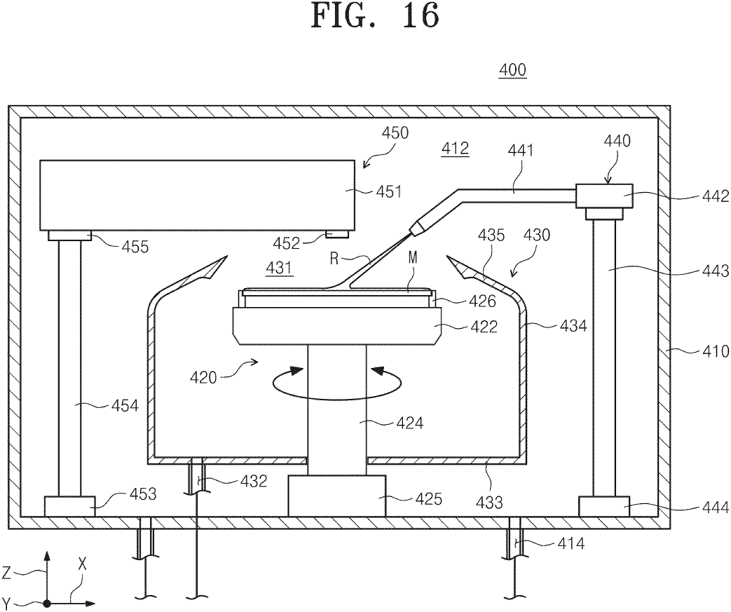

FIG. 9 is a flowchart of the substrate treating method according to an embodiment of the inventive concept, FIG. 10 is a flowchart of a critical dimension correction step of FIG. 9, FIG. 11 illustrates the substrate treating apparatus performing the treating liquid supply step of FIG. 10, FIG. 12 illustrates the substrate treating apparatus performing the reference image acquiring step of FIG. 10, and FIG. 13 illustrates an embodiment of the reference image acquired in FIG. 12, FIG. 14 illustrates the substrate treating apparatus performing the heating process of FIG. 10, FIG. 15 illustrates an embodiment of the substrate image acquired by the vision module when bubbles are generated during the heating process of FIG. 14, and FIG. 16 illustrates the substrate treating apparatus performing the rinsing step of FIG. 9.

Referring to FIG. 9, the substrate treating method may include a substrate taking in -step S100, a critical dimension correction step S200, a rinsing step S300, and a substrate taking-out step S600.

In the substrate taking-in step S100, a door may open a taking-out inlet formed in the housing 410. In addition, in substrate takin-in step S100, transfer robot 320 may mount the substrate M on the support unit 420.

If the substrate M is seated on the support unit 420, the critical dimension correction step S200 may be performed. In the critical dimension correction step S200, an etching of the pattern formed on the substrate M may be performed. In the critical dimension correction step S200, the pattern formed on the substrate M may be etched so that a critical dimension of the first pattern P1 and a critical dimension of the second pattern P2 coincide with each other. In the critical dimension correction step S200, a critical dimension correction process for correcting a critical dimension difference between the first pattern P1 and the second pattern P2 may be performed.

Referring to FIG. 10, the critical dimension correction step S200 may include a treating liquid supply step S210, a reference image acquiring step S220, and a heat treating step S230. In addition, the critical dimension correction step 200 may further include a step of determining whether to continue the critical dimension correction process if bubbles B are generated during the heat treatment. The step of determining whether to proceed with the critical dimension correction process may include a substrate image acquiring step S241, a comparing with a reference image step S242, and a determining whether to proceed a process step S243.

Referring to FIG. 10 and FIG. 11, the treating liquid supply step S210 may be a step of supplying a chemical C, which is an etchant, to the substrate M, by the liquid supply unit 440. In the treating liquid supply step S210, the support unit 420 may not rotate the substrate M. In order to accurately irradiate the laser L in a specific pattern in the heat treating step S230, which will be described later, it is necessary to minimize a distortion of the position of the substrate M when the substrate M is rotated. In addition, an amount of the chemical C supplied in the treating liquid supply step S210 may be supplied enough to allow the chemical C supplied on the substrate M to form a puddle. For example, the amount of the chemical C supplied in the treating liquid supply step S210 may cover an entire top surface of the substrate M, and may be supplied to an extent that the amount of chemical C does not flow down from or flows in a small amount from the substrate M. If necessary, the nozzle 441 may supply the treating liquid C to the entire top surface of the substrate M while changing its position.

Referring to FIG. 10 and FIG. 12, in the reference image acquiring step S220, the laser module 460 is turned on. In this case, both the vision module 470 and the lighting module 480 may be turned on. As the laser module 460 is turned on, the laser L is irradiated to a specific position of the substrate M to which the treating liquid C is applied. For example, the laser L may be irradiated to any one among the first pattern P1 and the second pattern P2 of the substrate M. For example, the laser L may be irradiated to the second pattern P2 of the substrate M. The vision module 470 may acquire the reference image by imaging a specific position of the substrate M to which the treating liquid C is applied. For example, the vision module 470 may acquire the reference image which images a specific portion of the substrate M including a position to which the laser L is irradiated. The vision module 470 may acquire the reference image acquired by imaging a portion of the substrate M including a point at which the laser L is irradiated. Referring to FIG. 13, the laser L may be displayed on the reference image.

Referring to FIG. 10 and FIG. 14, the heat treating step S230 of heating the substrate M may be performed after acquiring the reference image. In the heat treating step S230, the substrate M may be heated by irradiating the laser L with the substrate M. As shown in FIG. 14, in the heat treating step S230, the heating unit 450 is supplied with the chemical C to irradiate the laser L to the substrate M on which a liquid film is formed to heat the substrate M. In the heat treating step S230, the laser L may be irradiated to a specific region of the substrate M. A temperature of the specific region to which the laser L is irradiated may increase. Accordingly, an etching degree by the chemical C in the region to which the laser L is irradiated may increase. In addition, in the heat treating step S230, the laser L may be irradiated to any one of the first pattern P1 and the second pattern P2. For example, the laser L may be irradiated only to the second pattern P2 among the first pattern P1 and the second pattern P2. Accordingly, an etching ability of the chemical C to the second pattern P2 is improved. Accordingly, the critical dimension of the first pattern P1 may be changed from a first width (e.g., 69 nm) to a target critical dimension (e.g., 70 nm). In addition, the critical dimension of the second pattern P2 may be changed from a second width (e.g., 68.5 nm) to the target critical dimension (e.g., 70 nm). That is, it is possible to minimize a critical dimension deviation of the pattern formed on the substrate M by improving the etching ability for a partial region of the substrate M.

In the heat treating step S230, the vision module 470 may monitor a point at which the laser L is irradiated. The vision module 470 may monitor the point at which the laser L is irradiated in real time or may monitor the point at which the laser L is irradiated at predetermined time intervals. The vision module 470 may acquire the substrate image through a monitoring. The controller 30 may receive the substrate image monitored and acquired by the vision module 470. The controller 30 may determine whether the bubble B is generated through the substrate image of the vision module 470. If a specific position of the substrate M is heated by the laser L, bubbles B may be generated by a vaporization phenomenon of a liquid as the treating liquid C is heated to a temperature which is the same as, similar, or higher than the boiling point. The bubbles B interfere with a contact between the substrate M and the treating liquid C. In this case, there is a problem in that the etching ability of the treating liquid with respect to the substrate M is deteriorated or that the substrate M is not etched. Accordingly, if the occurrence of bubbles B is detected, the controller 30 may perform a step of determining whether to continue the critical dimension correction process. In addition, if it is determined that the bubbles B are above the reference value, the controller 30 may stop a critical dimension correction process in progress and may change process conditions for the substrate M to be treated afterward. For example, the controller 30 may change an output condition of the laser L of the laser module 460 and adjust an irradiation range of the laser L.

Referring to FIG. 10, the step of determining whether to continue the critical dimension correction process may include a substrate image acquiring step S241, a reference image comparing step S242, and a process determining step S243. In the substrate image acquiring step S241, the vision module 470 may acquire a substrate image by imaging a region of the substrate M on which the bubbles B are generated. Referring to FIG. 15, the vision module 470 may acquire the substrate image by monitoring a growth process of the bubbles B in real time as a local heating of the substrate M by the laser L is continuously performed. In addition, the vision module 470 may acquire the substrate image by monitoring the growth process of the bubbles B at regular time intervals as the local heating of the substrate M by the laser L continues. From FIGS. 15A to 15D, a heating time by the laser L increases, and thus a size of the bubbles B may grow.

The controller 30 may perform the image comparing step S242 of comparing the acquired substrate image with the reference image acquired at the reference image acquiring step S220. For example, the controller 30 may compare the reference image of FIG. 13 with the substrate image of FIGS. 15A to 15D, respectively.

Thereafter, the controller 30 may the process determining step S243. The controller 30 may determine whether a change amount between the reference image and the substrate image is 10% or lower in the process determining step S243. A change amount observation may be set to 10% to reduce a sensing error of the bubbles B or a growth error of the bubbles B. In this case, an error may mean an error in the substrate image acquired by the vision module 470. An error of the substrate image may include an error of the substrate image in which the bubbles B appear to be formed in the substrate image, or a size of the bubbles B appear to have grown more than the actual size of the bubbles B. For example, there may be a substrate image error due to a vibration of the substrate treating apparatus 1, a substrate image error due to a fluctuation of the treating liquid C supplied to the substrate M due to a downward airflow formed in the inner space 412 of the liquid treating chamber 400, or a substrate image error due to particles floating within the treating liquid C. The controller 30 compares and determines the change amount between the reference image and the substrate image at which the bubbles B are generated, and can generate an alarm if the change amount is 10% or more. If an alarm occurs, the laser L of the laser module 460 may be turned off, a process may be interrupted, and subsequently process conditions for the substrate M to be treated may be changed or reset.

In the step of determining whether to continue the process S243, if it is determined that the change amount between the reference image and the substrate image is 10% or lower, the process may be continued. That is, a heat treatment by the laser L may continue. Thereafter, if a set etching is completed, the laser L is turned off, and the critical dimension correction process for the corresponding substrate M may be terminated. For example, if the critical dimension of the first pattern P1 and the critical dimension of the second pattern P2 are etched to coincide within an error range, the critical dimension correction process may be terminated.

In the rinsing step S300, process by-products generated in the critical dimension correction step S200 may be removed from the substrate M. In the rinsing step S300, the rinsing liquid R may be supplied to a rotating substrate M to remove process by-products formed on the substrate M. If necessary, in order to dry a rinsing liquid R remaining on the substrate M, the support unit 420 may rotate the substrate M at a high speed to remove the rinsing liquid R remaining on the substrate M.

In the substrate taking-out step S400, the substrate M on which a treatment has been completed may be taken out from the inner space 412. In the substrate taking-out step S400, a door may open a taking-out inlet formed in the housing 410. In addition, in the substrate taking-out step S400, a transfer robot 320 may unload the substrate M from the support unit 420 and take out the unloaded substrate M from the inner space 412.

As the last step during a manufacturing process of the substrate M, a critical dimension correction process is performed to adjust a critical dimension deviation between the first pattern P1 (a monitoring pattern) and the second pattern P2 (an anchor pattern). In general, in the critical dimension correction process, since the treating liquid C is applied to the entire surface of the substrate M to simultaneously etch the first pattern P1 and the second pattern P2, a critical dimension deviation of the first pattern P1 and the second pattern P2 remains the same, making it difficult to secure optimized exposure conditions when manufacturing the substrate M. To solve this problem, a method of increasing the etching amount of a relevant point by irradiating the laser L to a point on the substrate M which should be etched more (for example the second pattern P2) is used. However, if the laser L increases a temperature of the local area on the surface of the substrate M, and the treating liquid C is heated to a temperature at or near the boiling point, bubbles B are generated by the vaporization of the liquid. If bubbles B are generated on the surface of the substrate M, the surface of the substrate M and the treating liquid C are not in contact with each other, and thus a etching ability is degraded.

However, according to the embodiment of the inventive concept, it is possible to monitor the point at which the laser L is irradiated by vision module 470 which is coaxial to the the laser module 460 by simultaneously imaging the point as when the laser L is irradiated, to suppress an etching effect decrease due to the bubbles B during the critical dimension correction process. Through this, it is possible to monitor whether bubbles B are generated on the substrate M and/or the treating liquid C and whether the bubbles B grow, so that process errors due to contacting with the bubbles B can be detected in advance. According to the embodiment of the inventive concept, since a generation of bubbles B continue to be monitored during the critical dimension correction process, process errors are checked before the end of the critical dimension correction process or before a final inspection step of the substrate M is found after the process is terminated, thus reducing the risk of process failure. In addition, it detects whether bubbles B occur and whether bubbles B grow during the process, and determines whether the process should continue in consideration of the error range, thereby saving process time and reducing costs.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
a housing;
a support unit positioned within the housing and configured to support a substrate;
a liquid supply unit configured to supply a treating liquid to the substrate supported on the support unit; and
a laser module configured to irradiate a laser to the substrate to which the treating liquid is supplied; and
a vision module for monitoring a point at which the laser is irradiated among the substrate.

2. The substrate treating apparatus of claim 1, wherein a laser irradiated from the laser module and an imaging axis of the vision module are provided to be coaxial.

3. The substrate treating apparatus of claim 1, further comprising a lighting module providing a lighting to a point at which the laser is irradiated among the substrate, and
wherein a lighting axis of the lighting module and an imaging axis of the vision module are provided to be coaxial.

4. The substrate treating apparatus of claim 1, further comprising a lighting module providing a lighting to a point at which the laser is irradiated among the substrate, and
wherein the laser module and the vision module are provided on a same plane, and the lighting module is provided below the vision module.

5. The substrate treating apparatus of claim 4, further comprising a body providing the laser module, the vision module and the light module therein, and
wherein an irradiation end is provided at the body, and
the laser of the laser module is irradiated to the substrate being coaxial with an imaging axis of the vision module, and
a lighting axis of a lighting of the lighting module is configured parallel to the imaging axis of the vision module.

6. The substrate treating apparatus of claim 1, wherein the vision module monitors whether a bubble has been generated and whether a size of the bubble grows during a process of heating the treating liquid applied on the substrate by the laser.

7. The substrate treating apparatus of claim 6, further comprising a controller for controlling the substrate treating apparatus, and
wherein whether a process which is being performed with respect to the substrate may be terminated is determined by comparing a reference image of the substrate acquired from the vision module and a substrate image of the substrate at which the bubble is generated which is acquired from the vision module.

8. The substrate treating apparatus of claim 7, wherein the controller continues a process which is proceeding on the substrate, if a change amount of the reference image and the substrate image is determined to be 10% or lower.

9. The substrate treating apparatus of claim 7, wherein the controller terminates a process which is proceeding on the substrate, if a change amount between the reference image and the substrate image is determined to be 10% or higher.

10. The substrate treating apparatus of claim 9, wherein the controller changes a process condition with respect to a substrate at which a process will be proceeded on afterward, if the process which is proceeding on the substrate is terminated, and
the controller controls the laser module so an output condition of the laser is changed or an irradiation range of the laser is changed.

11. The substrate treating apparatus of claim 1, wherein the substrate includes a first pattern and a second pattern formed at a different position from the first pattern, and
wherein the laser module irradiates the laser to any one pattern among the first pattern and the second pattern.

12. The substrate treating apparatus of claim 1, wherein the substrate includes a first pattern having a first critical dimension and a second pattern formed at a different position from the first pattern and which has a second critical dimension which is smaller than the first critical dimension, and
wherein the laser module irradiates the laser to the second pattern so the first critical dimension and the second critical dimension become the same.

13-19. (canceled)

20. A substrate treating apparatus comprising:
a housing;
a support unit positioned within the housing and configured to support a substrate;
a liquid supply unit configured to supply a treating liquid to the substrate supported on the support unit;
a heating unit configured to heat the substrate to which the treating liquid is supplied; and
a controller, and
wherein the heating unit comprises:
a body at which an irradiation end is provided;
a laser module provided within the body and irradiating a laser to the substrate to heat the substrate;
a vision module provided within the body for monitoring whether a bubble is generated at a point at which the laser is irradiated, and which is coaxial with the laser module; and
a lighting module provided within the body and providing a lighting to the point at which the laser is irradiated, and which is coaxial with the vision module, and
wherein the vision module acquires a reference image of the substrate immediately after the laser is turned on at the laser module, and acquires a substrate image at which the bubble is generated if the bubble is generated, and
the controller determines whether to continue proceeding with the process by comparing the reference image and the substrate image at which the bubble is generated, and terminates the process if a compare value is 10% or higher.
